(19) United States
(12) Patent Application Publication
(10) Pub. No.: US 2010/0243025 A1
(43) Pub. Date: Sep. 30, 2010

(54) Window[s] Treatment

(76) Inventors: Sneha P. Bhatia, Hackensack, NJ (US); Jayshiv Ramrakha, Hackensack, NJ (US); Nikhil P. Bhatia, Hasbrouck Heights, NJ (US); Prakash Bhatia, Hasbrouck Heights, NJ (US)

Correspondence Address: Daniel N. Beinart, 130 Hidden Rd, Andover, MA, 01810, US

(21) Appl. No.: 12/728,248

(22) Filed: Mar. 21, 2010

Related U.S. Application Data
(60) Provisional application No. 61/164,350, filed on Mar. 27, 2009.

(51) Int. Cl. H01L 31/042

(52) U.S. Cl. 136/244

(57) ABSTRACT

A windows treatment device includes a component for generating electrical current from incident light, a battery, and a component for generating light.

### CROSS-REFERENCE TO RELATED APPLICATIONS

This application claims priority to U.S. Provisional Application No. 61/164,350 filed Mar. 27, 2009, the entire contents of which are hereby incorporated by reference, as if fully set forth herein.

### FIELD OF THE INVENTION

The present invention relates generally to the field of window treatments, e.g., blinds, shades, and curtains, and more particularly to a window treatment device that captures solar energy to generate electrical power.

### BACKGROUND OF THE INVENTION

Existing window treatments serve their intended purposes of providing decor, reducing the amount of exterior light (sunlight, street lights, etc.) that enters an interior space of a building, house, etc. and providing privacy, i.e., preventing the persons or items in the interior space from being observed by someone exterior to the building. However, the energy contained in the sunlight incident upon the window treatment is for the most part reflected by existing window treatments, thereby dissipated in the exterior environment. A small amount of the solar energy may be absorbed, rather than reflected, by the window treatment, and this small amount of energy is subsequently released as heat energy to the interior space, which in the warmer season, may be undesirable. In either case, reflection or absorption, the solar energy incident upon the window treatment is not beneficially utilized.

Therefore a need exists for a window treatment device that in addition to providing decor and privacy and blocking exterior light, also puts at least a portion of the solar energy incident upon it to a beneficial use.

A device constructed according to the principles of the present invention addresses these deficiencies.

### BRIEF SUMMARY OF THE INVENTION

In accordance with principles of the present invention, a first embodiment of a windows treatment device includes one or more slats, one or more photovoltaic current generating components disposed on the slats, one or more batteries electrically coupled to the one or more photovoltaic current generating components, and one or more light generating components electrically coupled to the one or more batteries.

In accordance with principles of the present invention, a second embodiment of a windows treatment device includes one or more slats, one or more photovoltaic current generating components disposed on the slats, and an electrical outlet electrically coupled to the one or more photovoltaic current generating components.

In accordance with principles of the present invention, a third embodiment of a windows treatment device includes a shade, one or more photovoltaic current generating components disposed on the shade, and an electrical outlet electrically coupled to the one or more current generating components.

### BRIEF DESCRIPTION OF THE DRAWINGS

In the drawings:

FIG. 1 is a schematic diagram of a first embodiment of a windows treatment device in accordance with principles of the present invention;

FIG. 2 is a schematic diagram of a second embodiment of a windows treatment device in accordance with principles of the present invention; and

FIG. 3 is a schematic diagram of a third embodiment of a windows treatment device in accordance with principles of the present invention; and

FIG. 4 is a front view of the embodiment of a windows treatment device of FIG. 1.

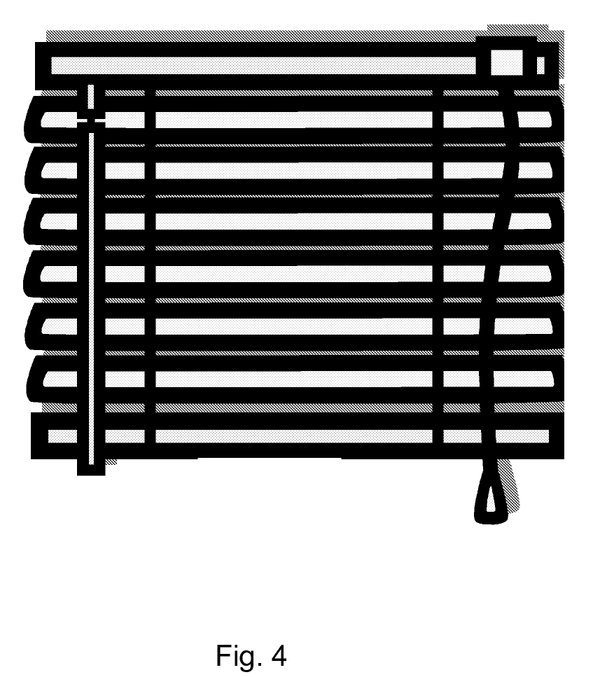

Other objects and features of the present invention will become apparent from the detailed description considered in connection with the accompanied drawings. It is to be understood however, that the drawings are designed as an illustration only and not as definition of the limits of the invention. It is obvious that many changes and modifications may be made thereunto without departing from the spirit and scope of the invention.

### DETAILED DESCRIPTION OF THE INVENTION

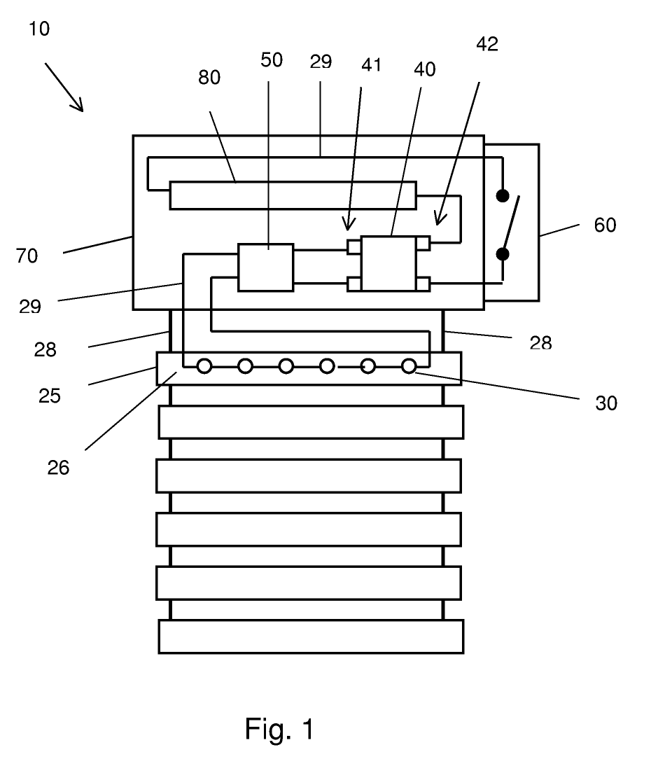

FIG. 1 is a schematic diagram of a first embodiment of a windows treatment device in accordance with principles of the present invention. The windows treatment device 10 comprises horizontal slats 25, cords 28, electrical wires 29, a battery 40, a battery charging control unit 50, a switch 60, a header 70, and a light generating component 80. Each slat 25 has an exterior-facing side 26 comprised of one or more photovoltaic current generating components 30 that are electrically coupled by electrical wires 29 to the battery charging control unit 50 which is in turn electrically coupled to charging terminals 41 of the battery 40. (For simplicity, FIG. 1 depicts only the photovoltaic current generating components 30 and electrical wires 29 for a single slat.) The output terminals 42 of the battery 40 are electrically coupled to the switch and to the light generating component 80.

In the embodiment depicted in FIG. 1, the cords 28 are connected to the header 70 and slats 25 in a fashion similarly to that of an ordinary horizontal slat window blind. By operating the cords 28, the slats 25 can be raised toward, or lowered away from, the header 70. As with an ordinary horizontal slat window blind, the slats can be operated to be in a fully raised, partially lowered, or fully lowered configuration. The electrical wires 29 are disposed substantially alongside the cords 28 so that the slats 25 can be raised and lowered without breaking the insulation that surrounds the electrical wires 29 or otherwise interfering with the electrical function of the electrical wires 29.

In operation, the windows treatment device 10 is installed in front of a window or other area, such as a window embedded in a door, through which sunlight is received. This embodiment, and any of the other embodiments described herein, may be permanently or semi-permanently installed in front of a window, or may be portable and installed in front of a window as needed on a temporary basis. When the slats 25 are in either a partial or fully lowered configuration, the photovoltaic current generating components 30 that are on the exterior side 26 of each lowered slat 25 receive exterior light that comes through the window. The received light, if of sufficient strength, will cause the photovoltaic current generating components 30 to generate an electric current that will be received by the battery charging control unit 50. The battery charging control unit 50 controls the charging current that is provided to the battery 40, allowing charging current to be provided when the battery 40 is able to receive additional electrical charge and preventing charging current from being provided to the battery 40 when the battery has obtained its maximum electrical charge.

When the battery 40 has sufficient electrical charge, switch 60, when operated by a person, allows current to flow from the battery 40 to the light generating component 80. Thus in typical operation, a person operates the cords 28 to place the slats 25 in a partially or fully lowered configuration during the day, thus blocking sunlight from entering the interior space of the building and also charging the battery 40. Then, during the evening or at night, the person operates the switch 60 to cause the light generating component 80 to act as a light source, providing illumination within the interior space of the building.

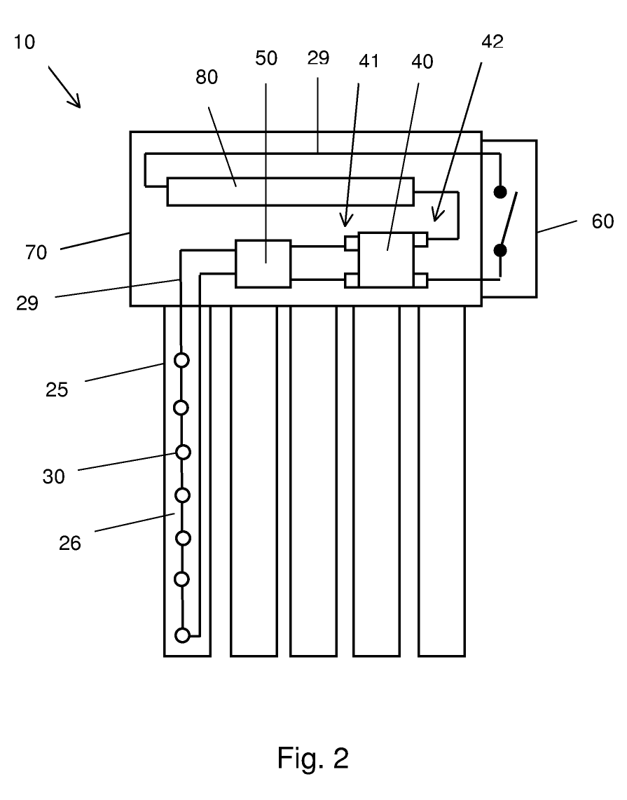

FIG. 2 is a schematic diagram of a second embodiment of a windows treatment device in accordance with principles of the present invention. The windows treatment device 10 comprises vertical slats 25, electrical wires 29, a battery 40, a battery charging control unit 50, a switch 60, a header 70, and a light generating component 80. Each slat 25 has an exterior side 26 comprised of one or more photovoltaic current generating components 30 that are electrically coupled by electrical wires 29 to the battery charging control unit 50 which is in turn electrically coupled to charging terminals 41 of the battery 40. (For simplicity, FIG. 2 depicts only the photovoltaic current generating components 30 and electrical wires 29 for a single slat.) The output terminals 42 of the battery 40 are electrically coupled to the switch 60 and to the light generating component 80.

In the embodiment depicted in FIG. 2, the slats 25, using well-known means used in the design of vertical slat window blinds, are hung from the header 70 and can be rotated within a range of orientation from substantially parallel (fully closed) to substantially perpendicular (fully opened) to the plane of a window. As with an ordinary vertical slat window blind, the slats can be operated to be in a fully opened, partially closed, or fully closed configuration.

In operation, the windows treatment device 10 is installed in front of an exterior window. When the slats 25 are in either a partial or fully closed configuration, the photovoltaic current generating components 30 that are on the exterior side 26 of each slat 25 receive exterior light that comes through the window. The received light, if of sufficient strength, will cause the photovoltaic current generating components 30 to generate an electric current that will be received by the battery charging control unit 50. The battery charging control unit 50 controls the charging current that is provided to the battery 40, allowing charging current to be provided when the battery 40 is able to receive additional electrical charge and preventing charging current from being provided to the battery 40 when the battery has obtained its maximum electrical charge.

When the battery 40 has sufficient electrical charge, switch 60, when operated by a person, allows current to flow from the battery 40 to the light generating component 80. Thus in typical operation, a person operates the windows treatment device 10 to place the slats 25 in a partially or fully closed configuration during the day, thus blocking sunlight from entering the interior space of the building and also charging the battery 40. Then, during the evening or at night, the person operates the switch 60 to cause the light generating component 80 to act as a light source, providing illumination within the interior space of the building.

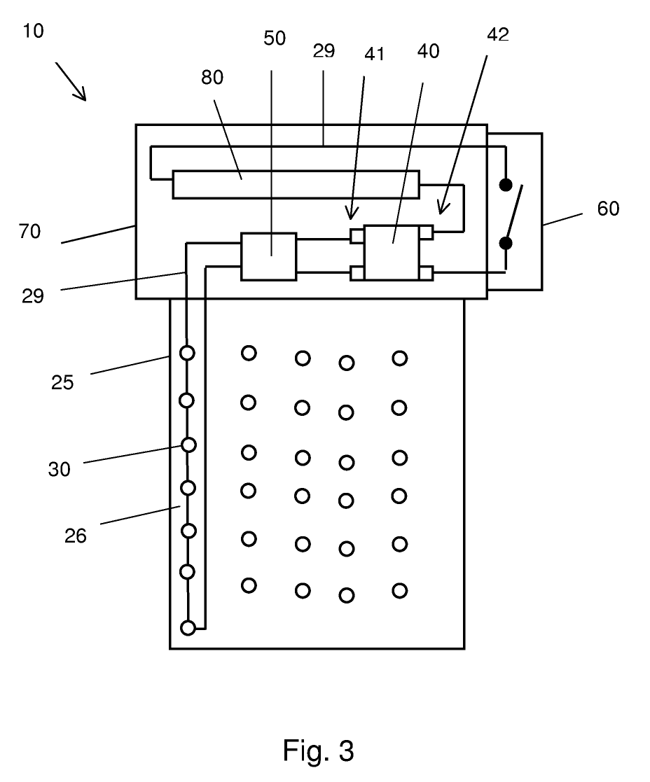

FIG. 3 is a schematic diagram of a third embodiment of a windows treatment device in accordance with principles of the present invention. The windows treatment device 10 comprises a shade 90, electrical wires 29, a battery 40, a battery charging control unit 50, a switch 60, a header 70, and a light generating component 80. The shade 90 has an exterior side 91 comprised of one or more photovoltaic current generating components 30 that are electrically coupled by electrical wires 29 to the battery charging control unit 50 which is in turn electrically coupled to charging terminals 41 of the battery 40. (For simplicity, FIG. 3 depicts only a subset of the electrical wires 29.) The output terminals 42 of the battery 40 are electrically coupled to the switch 60 and to the light generating component 80.

In the embodiment depicted in FIG. 3, the shade 90, using well-known means used in the design of window shades, is hung from the header 70 and can be raised toward, or lowered away from, the header 70. As with an ordinary window shade, the shade can be operated to be in a fully raised, partially lowered, or fully lowered configuration.

As is well-known in the art, a shade 90 may be rolled about a roller (not shown) and unrolled from and rolled back on the roller to be raised or lowered. In addition, as is also well-known, a shade 90 may be pleated.

In operation, the windows treatment device 10 is installed in front of an exterior window. When the shade 90 is in either a partial or fully lowered configuration, the photovoltaic current generating components 30 that are on the exterior side 26 of the shade 90 receive exterior light that comes through the window. The received light, if of sufficient strength, will cause the photovoltaic current generating components 30 to generate an electric current that will be received by the battery charging control unit 50. The battery charging control unit 50 controls the charging current that is provided to the battery 40, allowing charging current to be provided when the battery 40 is able to receive additional electrical charge and preventing charging current from being provided to the battery 40 when the battery has obtained its maximum electrical charge.

When the battery 40 has sufficient electrical charge, switch 60, when operated by a person, allows current to flow from the battery 40 to the light generating component 80. Thus in typical operation, a person operates the windows treatment device 10 to place the shade 90 in a partially or fully lowered configuration during the day, thus blocking sunlight from entering the interior space of the building and also charging the battery 40. Then, during the evening or at night, the person operates the switch 60 to cause the light generating component 80 to act as a light source, providing illumination within the interior space of the building.

A slat 25 in the first and second embodiments of a windows treatment device of FIGS. 1 and 2, or a shade 90 in the third embodiment of a windows treatment device of FIG. 3, may be of any suitable material that will allow for the disposition of one or more photovoltaic current generating components 30 on its exterior side. For example, a slat 25 or a shade 90 may comprise plastic, acrylic, fiberglass, polymers of plastic and glass, paper, recycled cardboard, cork, fabric, cloth, rubber, metal alloys, aluminum, silk, bamboo, wicker, wood, nylon, polyester & polymers and hybrids of the above materials. A photovoltaic component 30 may be any of well-known devices, including solar cells, solar modules, and photovoltaic arrays, for converting incident light (in this case sunlight) into electric current.

As in conventional window treatment devices, a slat 25 in the first and second embodiments of a windows treatment device of FIGS. 1 and 2, or a shade 90 in the third embodiment of a windows treatment device of FIG. 3, may be opaque (light blocking), translucent (light reducing) or light diffusing, each case providing some measure of reduction of the light that enters the interior space of a building and privacy to persons in the interior space.

One skilled in the art will recognize that a light generating component 80 may be any of various well-known types of components that generate light output by converting input electric current. For example, light generating component 80 may be a fluorescent, incandescent or halogen light bulb, or LED light source.

In other embodiments of a window treatment device 10 having slats 25, one or more light generating components 80 may be disposed on the interior-facing sides of the slats 25, rather than on the header 70. In operation, a person typically places the slats 25 in a partially or fully lowered configuration before operating the switch 60 to cause the light generating components 80 to act as light sources.

Other embodiments of a window treatment device 10 also include an electric outlet electrically coupled to the battery 40, and may or may not include the light generating component 80. The electric outlet can receive an electrical plug and thus deliver electrical current to an external appliance or device electrically coupled to the plug.

One skilled in the art will recognize that a switch 60 may be a manually operated switch (as described above) or may be another type of well-known switch. For example, a timer switch, switching on and off at prescribed times, or a light-sensing switch, switching on if the level of interior light falls below a prescribed level and off if the level of interior light exceeds the prescribed level, may be used. In addition, other well-known types of manual switch may be used, e.g., a dimmer switch.

Furthermore, one skilled in the art will recognize that the movement of slats 25 of a window treatment device 10 between the open and closed configurations (and in between) may be manually performed (as described above) or may be assisted with the aid of one or more motors (not shown). In addition, the operation of the motors may be accomplished via a manual switch or may utilize remote control means (not shown) to control the operation of the slats 25.

A window treatment device 10 as described herein, in addition to serving a conventional window treatment's functions of providing decor and privacy and blocking, reducing or diffusing exterior light, puts at least a portion of the solar energy incident upon it to a beneficial use by providing electric current to provide light or for other purposes.

While a particular form and use of the present invention has been described above, the invention is not limited to the specific arrangement of parts or manner of use described.

One skilled in the art understands that modifications to the construction and use of the present system may be made without departing from the scope of the invention.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention. This disclosure is intended to cover any adaptations or variations of the embodiments discussed herein.

1. A windows treatment device, the device comprising:
a window treatment component having an exterior-facing side upon which are disposed one or more photovoltaic current generating components generating a first electrical current from light incident upon said photovoltaic current generating components, and an opposing interior-facing side;
one or more batteries receiving said first electrical current and converting said electrical current into electrical charge, storing said electrical charge, and providing a second electrical current derived from said electrical charge, said one or more batteries electrically coupled to said one or more photovoltaic current generating components; and
one or more light generating components receiving said second electrical current and generating light from said second electrical current, said one or more light generating components disposed upon said interior-facing side of said window treatment component and electrically coupled to said one or more batteries.

2. The windows treatment device of claim 1, said window treatment component having a characteristic selected from the group consisting of light blocking, light reducing and light diffusing.

3. A windows treatment device, the device comprising:
a window treatment component having an exterior-facing side upon which are disposed one or more photovoltaic current generating components for generating electrical current from light incident upon said photovoltaic current generating components;
one or more batteries receiving said first electrical current and converting said electrical current into electrical charge, storing said electrical charge, and providing a second electrical current derived from said electrical charge, said one or more batteries electrically coupled to said one or more photovoltaic current generating components; and
an electrical outlet receiving said second electrical current and providing said second electrical current to an electrical plug, said electrical outlet electrically coupled to said one or more batteries.

4. The windows treatment device of claim 3, said window treatment component having a characteristic selected from the group consisting of light blocking, light reducing and light diffusing.

5. A windows treatment device, the device comprising:
a window treatment component having one or more slats each having an exterior-facing side upon which are disposed one or more photovoltaic current generating components generating a first electrical current from light incident upon said photovoltaic current generating components;
one or more batteries receiving said first electrical current and converting said electrical current into electrical charge, storing said electrical charge, and providing a second electrical current derived from said electrical charge, said one or more batteries electrically coupled to said one or more photovoltaic current generating components; and
an electrical outlet for receiving said second electrical current and providing said second electrical current to an electrical plug, said electrical outlet electrically coupled to said one or more batteries.

6. The windows treatment device of claim 5, said one or more slats having a characteristic selected from the group consisting of light blocking, light reducing and light diffusing.

7. The windows treatment device of claim 5, wherein the orientation of said one or more slats is selected from the group consisting of horizontal and vertical.

8. The windows treatment device of claim 5, the device further comprising:
one or more light generating components for receiving said second electrical current from said one or more batteries, said one or more light generating components electrically coupled to said one or more batteries.

9. The windows treatment device of claim 5, each of said slats having an interior-facing side opposite to said exterior-facing side, wherein said one or more light generating components are disposed upon the interior-facing sides of said slats of said window treatment component.

10. The windows treatment device of claim 5, further comprising a header and two or more cords attached to said header and said one or more slats, wherein said one or more slats may be retracted towards said header by operation of said cords.

11. (canceled)

12. (canceled)
